(19) United States
(12) Patent Application Publication
(10) Pub. No.: US 2008/0048326 A1
(43) Pub. Date: Feb. 28, 2008

(54) SEMICONDUCTOR DEVICE

(76) Inventor: Jae-Won Han, Gyeongi-do (KR)

Correspondence Address: SHERR & NOURSE, PLLC, 620 HERNDON PARKWAY, SUITE 200, HERNDON, VA, 20170, US

(21) Appl. No.: 11/846,263

(22) Filed: Aug. 28, 2007

(30) Foreign Application Priority Data
Aug. 28, 2006 (KR) 10-2006-0081961

(51) Int. Cl. H01L 23/48; H01L 21/44

(52) U.S. Cl. 257/751; 438/653; 257/E21.476; 257/E23.01

(57) ABSTRACT

According to embodiments, a semiconductor device may include a PMD layer provided with a contact, and a wiring layer formed on the PMD layer and connected to the contact by stacking and forming a plurality of metal layers thereon. In embodiments, the plurality of metal layers may include a first metal layer and a second metal layer.

The present application claims priority under 35 U.S.C. 119 and 35 U.S.C. 365 to Korean Patent Application No. 10-2006-0081961 (filed on Aug. 28, 2006), which is hereby incorporated by reference in its entirety.

### BACKGROUND

An image sensor may be a semiconductor device configured to convert an optical image into an electrical signal. A charge coupled device (CCD) may be a device having a structure where the respective metal-oxide-silicon (MOS) capacitors may be positioned adjacently to each other and may store and transmit a charge carrier in the capacitor. Further, a complementary MOS (CMOS) image sensor may be a device adopting a switching manner that includes as many MOS transistors as there are pixels, and controls the device using CMOS technology, including a control circuit and a signal processing circuit as peripheral circuits and that sequentially detects outputs from the device.

### SUMMARY

Embodiments relate to a semiconductor device and a method of fabricating a semiconductor device.

Embodiments relate to a semiconductor device and a method of fabricating a semiconductor device that may be capable of stably forming a fine wiring.

According to embodiments, a semiconductor device may include a PMD layer provided with a contact, and a wiring layer formed on the PMD layer and connected to a contact by stacking and forming a plurality of metal layers thereon, wherein the plurality of metal layers comprises a first metal layer and a second metal layer.

According to embodiments, a method of fabricating a semiconductor device may include forming a PMD layer provided with a contact, and forming a wiring layer connected to the contact on the PMD layer by stacking and forming a plurality of metal layers thereon, wherein the plurality of metal layers comprises a first metal layer and a second metal layer.

### DRAWINGS

FIGS. 1 to 4 are drawing illustrating a semiconductor device and method of fabricating a semiconductor device according to embodiments.

### DESCRIPTION

FIG. 4 is a drawing illustrating a semiconductor device according to embodiments.

Referring to FIG. 4, according to embodiments, a semiconductor device, may include a first metal layer 20 and a second metal layer 30, which may be first stacked and formed on pre metal dielectric (PMD) layer 10. PMD layer 10 may be provided with a contact, and wiring layer 50 connected to the contact may be formed thereon.

In embodiments, the metal wiring may not be formed of a single metal layer, but may be formed in a structure where first metal layer 20 and second metal layer 30 may be stacked and formed.

According to embodiments, as illustrated in FIG. 4, two metal layers may be stacked to form the metal wiring. However, in embodiments, the metal wiring may be formed by stacking any number of layers, for example three or more metal layers.

First metal layer 20 may include first lower barrier layer 21, first Al layer 23, and first upper barrier layer 25. In embodiments, first lower barrier layer 21 may be formed of any one selected from Ti, TiN, and Ti/TiN, and first upper barrier layer 25 may be formed of any one selected from Ti, TiN, and Ti/TiN.

Second metal layer 30 may include second Al layer 31 and second upper barrier layer 33. Second upper barrier layer 33 may be formed of any one selected from Ti, TiN, and Ti/TiN.

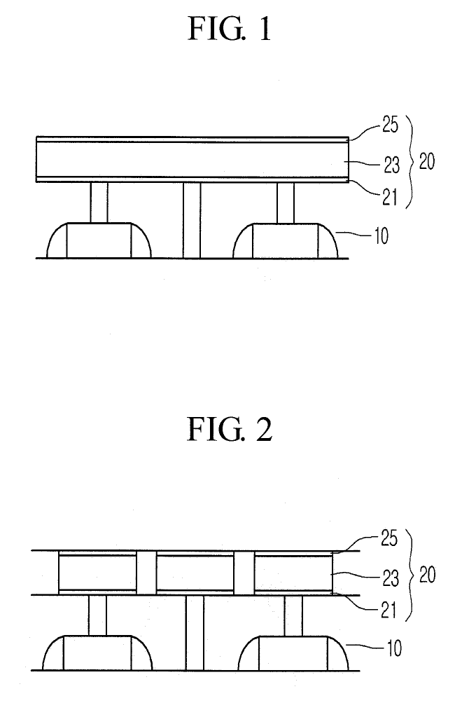

FIGS. 1 to 4 are drawings illustrating a semiconductor device according to embodiments and a method of fabricating a semiconductor device according to embodiments.

According to embodiments, as illustrated in FIGS. 1 to 4, pre metal dielectric (PMD) layer 10 having a contact may be first formed.

First layer 20 and second layer 30 may be stacked and formed on PMD layer 10 and wiring layer 50 connected to a contact may be formed thereon. In embodiments, when forming the metal wiring, the metal wiring may not just be formed of a single metal layer, but may be formed in a structure where first metal wire 20 and second metal wire 30 may be stacked and formed.

In embodiments, two metal layers may be stacked to form the metal wiring. In embodiments, the metal wiring may be formed by stacking any number of metal layers, for example, three or more metal layers.

First metal layer 20 may be formed to include first lower barrier layer 21, first Al layer 23, and first upper barrier layer 25. In embodiments, first lower barrier layer 21 may be formed of any one selected from Ti, TiN, and Ti/TiN and may be formed at a thickness of 100 to 400 Å. In embodiments, first upper barrier layer 25 may be formed of any one selected from Ti, TiN, and Ti/TiN and may be formed at a thickness of 100 to 1000 Å.

Second metal layer 30 may formed to include second Al layer 31 and second upper barrier layer 33. Second upper barrier layer 33 may be formed of any one selected from Ti, TiN, and Ti/TiN and may be formed at a thickness of 100 to 1000 Å.

First Al layer 23 and second Al layer 31 may be formed at a thickness of 500 to 2000 Å.

A fabrication method of the semiconductor device according to embodiments will be described with reference to FIGS. 1 to 4.

Referring to FIG. 1, first metal layer 20 may include first lower barrier layer 21, first Al layer 23, and first upper barrier layer 25 formed over the PMD layer 10.

First lower barrier layer 21 may use any one of Ti, TiN, and Ti/TiN according to a use and its total thickness may be formed to have a thickness of approximately 100 to 400 Å. First upper barrier layer 25 may be formed of TiN and its total thickness may be formed to have a thickness of approximately 100 to 1000 Å. Anti-reflective film of organic material or inorganic material may be applied. First Al layer 23 may be formed to have a thickness of approximately 500 to 2000 Å at a level of a 130 nm.

According to embodiments, if first metal layer 20 is formed having a Ti/TiN/Al/TiN structure, it may be formed at a thickness of approximately 50˜200/50˜200/500˜2000/100˜1000 Å.

Referring to FIG. 2, after patterning first metal layer 20, an insulating layer may be formed and a planarization process may be performed.

The planarization process may use a chemical mechanical polishing method, according to embodiments. In the planarization process, first Al layer 23 may not be exposed and the planarization process may stop at first upper barrier layer 25.

In embodiments, first Al layer 23 may be exposed. In such a case, its surface may be oxidized and attacked, for example by CMP slurry, oxygen, etc., and a contact of first Al layer 23 and second Al layer 31 deposited later may not be good so that resistance may be increased.

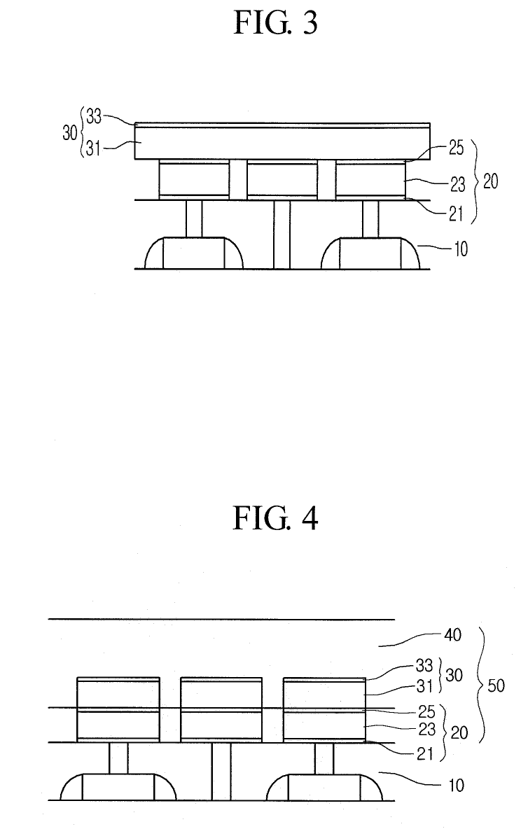

Referring to FIG. 3, second metal layer 30 may include second Al layer 31 and second upper barrier layer 33 on the metal layer 20.

In embodiments, second upper barrier layer 33 may use any one of Ti, TiN, and Ti/TiN according to a use and its total thickness may be formed to be approximately 100 to 1000 Å. Anti-reflective film of organic material or inorganic material may be formed. Second Al layer 31 may be formed to have a thickness of approximately 500 to 2000 Å at a level of a 130 nm.

In embodiments, if second metal layer 30 is formed in Al/Ti/TiN structure, its thickness may be formed to be approximately 500˜2000/50˜200/50˜900 Å.

Prior to forming second Al layer 31, a surface of first upper barrier layer 25 may be oxidized by performing the plasma processing or a surface of first Al layer 23 capable of being exposed and oxidized by the CMP non-uniform defect may be processed.

In embodiments, plasma processing may be performed using Ar or NH3. After the plasma processing, second Al layer 31 and second upper barrier layer 33 may be deposited without having vacuum break.

Referring to FIG. 4, after patterning second metal layer 30, insulating layer 40 may be formed and a planarization process may be performed. According to embodiments, a thickness of insulating layer 40 may be determined as needed and the CMP may stop at a prescribed time point so that insulating layer 40 having a desired thickness may be formed.

According to embodiments, the metal wiring may be formed by stacking the plurality of metal layers so that a thickness of the metal layer etched once in an etch process for patterning may be reduced. As a result, in performing the pattering on the metal layer, a phenomenon that a photo resist may collapse may be prevented and a fine wiring may be formed using Al.

According to embodiments, subsequent processes such as a via process, etc., for fabricating the semiconductor device may be performed and in the case of fabricating an image sensor, a plurality of wiring layers forming process, a color filter forming process, a micro lens forming process, and the like may be performed.

According to embodiments, a semiconductor device and a method of fabricating a semiconductor device may form a stable fine wiring.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method, comprising:
forming a pre metal dielectric (PMD) layer provided with a contact;
forming a first metal layer over the PMD layer; and
forming a second metal layer over the first metal layer and coupled to the first metal layer, wherein the first metal layer and the second metal layer are electrically connected with the contact.

2. The method of claim 1, further comprising:
forming first metal film patterns over the PMD layer;
forming the first metal layer by filling a first interlayer dielectric material between the first metal film patterns;
forming second metal film patterns over the first metal layer; and
forming the second metal layer by filling a second interlayer dielectric material between the second metal film patterns.

3. The method of claim 2, wherein the first metal layer comprises a lower barrier layer, a first aluminum (Al) layer, and a first upper barrier layer.

4. The method of claim 3, wherein the lower barrier layer comprises Ti/TiN, and the first upper barrier layer comprises TiN such that the first metal layer comprises Ti/TiN/Al/TiN formed to have respective thicknesses of approximately 50˜200/50˜200/500˜2000/100˜1000 Å.

5. The method of claim 3, wherein the lower barrier layer comprises one of Ti, TiN, and Ti/TiN.

6. The method of claim of claim 5, wherein the lower barrier layer is formed to have a thickness of approximately 100-400 Å.

7. The method of claim 3, wherein the second metal layer comprises a second Al layer and a second upper barrier layer.

8. The method of claim 7, wherein each upper barrier layer comprises one of Ti, TiN, and Ti/TiN.

9. The method of claim 8, wherein each upper barrier layer is formed to have a thickness of approximately 100-1000 Å.

10. The method of claim 7, wherein the second aluminum layer and second upper barrier layer are formed over the first metal layer without having a vacuum break in the manufacturing process.

11. A device, comprising:
a pre metal dielectric (PMD) layer provided with a contact;
a first metal layer over the PMD layer and electrically coupled to the contact; and
a second metal layer over the first metal layer and electrically coupled to the first metal layer.

12. The device of claim 11, wherein the first metal layer is formed by forming first metal film patterns over the PMD layer and by filling a first interlayer dielectric material between the first metal film patterns, and wherein the second metal film pattern is formed by forming second metal film patterns over the first metal layer, and filling a second interlayer dielectric material between the second metal film patterns.

13. The device of claim 11, wherein the first metal layer comprises a lower barrier layer, a first aluminum (Al) layer, and a first upper barrier layer.

14. The device of claim 13, wherein the lower barrier layer comprises Ti/TiN, and the first upper barrier layer comprises TiN such that the first metal layer comprises Ti/TiN/Al/TiN formed to have respective thicknesses of approximately 50˜200/50˜200/500˜2000/100˜1000 Å.

15. The device of claim 11, wherein the second metal layer comprises a second Al layer and a second upper barrier layer.

16. The device of claim 15, wherein the second upper barrier layer comprises Ti/TiN such that the second metal layer comprises Al/Ti/TiN formed to have respective thicknesses of approximately 500˜2000/50˜200/50˜900 Å.

17. A wiring layer, comprising:
a first metal layer; and
a second metal layer formed over the first metal layer, wherein the first metal layer comprises a lower barrier layer, a first aluminum (Al) layer formed over the lower barrier layer, and a first upper barrier layer formed over the first aluminum layer, and wherein the second metal layer comprises a second aluminum (Al) layer and a second upper barrier layer formed over the second aluminum layer.

18. The wiring layer of claim 17, wherein the first metal layer is formed over a pre-metal dielectric (PMD) layer.

19. The wiring layer of claim 17, wherein the first and second aluminum layers are each formed to have a thickness of approximately 500-2000 Å, and wherein the first and second upper barrier layers are each formed to have a thickness of approximately 100-1000 Å.

20. The wiring layer of claim 19, wherein the first and second upper barrier layers and the lower barrier layer each comprise one of Ti, TiN, and Ti/TiN.
